(19) United States
(12) Patent Application Publication
(10) Pub. No.: US 2005/0207232 A1
(43) Pub. Date: Sep. 22, 2005

(54) Access method for a NAND flash memory chip, and corresponding NAND flash memory chip

(76) Inventors: Eckhard Delfs, Nurnberg (DE); Uwe Hildebrand, Erlangen (DE)

Correspondence Address: MOSER, PATTERSON & SHERIDAN, LLP;GERO G. MCCLELLAN/INFINEON, 3040 POST OAK BLVD.,, SUITE 1500, HOUSTON, TX, 77056, US

(21) Appl. No.: 11/083,783

(22) Filed: Mar. 18, 2005

(30) Foreign Application Priority Data
Mar. 18, 2004 (DE) 10 2004 013 493.6

(51) Int. Cl. G11C 11/34

(52) U.S. Cl. 365/185.33; 711/103

(57) ABSTRACT

In the access method for a memory chip, particularly for a NAND flash memory chip, the memory access is dependent upon what type of memory chip is used. In this case, the method is intended to support various types of memory chip. According to the inventive method, data are first read from the memory chip which contain a memory-chip-typical information item for the access to the memory chip. The subsequent access to the memory chip is performed using the memory-chip-typical information item contained in the data.

### CROSS-REFERENCE TO RELATED APPLICATIONS

This application claims foreign priority benefits under 35 U.S.C. §119 to co-pending German patent application number DE 10 2004 013 493.6, filed 18 Mar. 2004. This related patent application is herein incorporated by reference in its entirety.

### BACKGROUND OF THE INVENTION

1. Field of the Invention

The invention relates to an access method for a memory chip, particularly for a NAND flash memory chip, where at least one access instruction used according to access type is dependent on the type of memory chip used. The invention also relates to a corresponding memory chip.

2. Description of the Related Art

Multifunctional mobile radios, MP3 players, PDAs (Personal Digital Assistant) and other highly complex small appliances are enjoying increasing popularity. Such appliances frequently comprise large non-volatile read-only memories which can be used to store complex operating systems, a multiplicity of applications and memory-intensive user data. Increasingly, the electrically rewritable read-only memory (EEPROM—electrical erasable and programmable read-only memory) used for this purpose is a NAND flash memory, which is replacing the traditionally used NOR flash memory in many instances of application. The reason for the market success of the NAND flash memory is that the storage density of the NAND flash memory is higher than that of the NOR flash memory and hence the costs per megabyte are lower.

NAND flash memories and NOR flash memories sometimes differ significantly in terms of memory access: a NOR flash memory typically supports random access at byte or word level, and a NAND flash memory typically does not support random access of this type. In the case of the NAND flash memory, the memory access is generally handled indirectly via a two-way 8-bit I/O interface. To this end, this interface may be used to transmit an appropriate access instruction, which comprises a command statement and an address statement, to the command and address registers inside the memory. In the case of the NAND flash memory, the read access and the write access typically take place at the page level, in contrast to the byte or word level in the NOR flash memory, with a “page” being a memory area of between 256 bytes and 2048 bytes in size, depending on the type of the NAND flash memory.

One difficulty with the NAND flash memory is that the access instruction, for example the read instruction for reading data from the NAND flash memory, is typically dependent on the type of NAND flash memory used. This generally relates both to the command statement and to the address statement.

The variability of the access may be important, particularly for manufacturers of such systems as are operated with a large number of different types of NAND flash memories on account of the different requirements of the customers. The system therefore needs to send the respective valid access instruction to the NAND flash memory according to the type used.

Usually when a system is started up (called the boot process), it is necessary for information stored in a NAND flash memory (for example program instructions or other data) to be able to be read from the memory. In this case, the access operations to be performed during start-up may be stored in a “boot ROM” (Read-Only Memory). There are several possible methods of deriving a proper access instruction during the boot process for accessing the memory.

To derive the access instruction which is valid according to memory type for the NAND flash memory used, the system may request the type of NAND flash memory being used using a special instruction. In this case, the flash memory typically outputs a manufacturer number (one byte) and a type number (one byte), with the type number coding information such as the operating voltage, the memory size and the memory organization. Depending on these two numbers, it is possible to derive the respective valid access instruction, including the read instruction. A drawback of this solution is the risk of incompatibility. In this case, it is possible for the manufacturers of NAND flash memories, particularly new manufacturers, not to follow the conventions relating to the manufacturer number and the type number, which means that a memory type with an access instruction which is known to the system but an incorrect manufacturer number and/or type number cannot be supported by the system. In addition, future NAND flash memories with new manufacturer numbers and/or type numbers which are not known to the system cannot be identified and hence cannot be supported without updating the system. In this case, updating the system, particularly updating the boot ROM, is associated with additional cost and complexity.

In some cases, the system may be able to read type-specific information from the NAND flash memory by connecting up configuration pins on the processor chip in order to perform the access to the NAND flash memory, including the read access, in line with this type-specific information. This approach may also be used to identify the bus width (8 or 16 bits) of the I/O interface for the NAND flash memory used. A drawback of this solution is that the reading is associated with additional hardware complexity.

In other cases, not only the NAND flash memory but also an additional read-only memory, for example a dedicated EEPROM or an additional NOR flash memory, is provided which carries the information which is needed to access the NAND flash memory. A drawback of this solution is the additional hardware complexity.

In other cases, when attempting to access a NAND flash memory during a system's boot process, some types of NAND flash memories output the data content of a particular memory area without a specific read instruction after the NAND flash memory has been reset. This is typically the data content of page 0 in block 0. A drawback of reading without a specific read instruction is that this approach is supported only by a few types of NAND flash memories. In addition, the reading system may lack information item relating to the size of a page, which means that it cannot identify the last byte of the serially read sequence of bytes from the page without an appropriate indication. In some cases, to indicate the last byte, the last byte may be repeated, but this indication is not reliable. Furthermore, this method can be used to read just one particular memory area (page 0 in block 0) of the NAND flash memory. Using this method, it is not possible to read any other memory content of the NAND flash memory.

Besides the aforementioned difficulties relating to determining the proper read instruction, it may also be necessary to observe memory-chip-typical differences in the actual reading of the data, i.e. after the read instruction has been input. For example, in a NAND flash memory, the reading system typically needs to have knowledge about the size of a page which has been read so that the end of the data sequence transmitted via the I/O interface can be identified with certainty.

Accordingly, what is needed is a flexible access method for a large number of types of memory chips, including for a large number of types of NAND flash memory chips. Preferably, the access method should also be configured to be flexible so that it supports future types of memory chips without updating, and additional hardware components needed to carry out the access method should be avoided or minimized.

### SUMMARY OF THE INVENTION

Embodiments of the present invention provide a method and system for accessing a memory chip in a manner dependent on a type of the memory chip. The method comprises reading first data from the memory chip using a first read instruction, wherein the first data is stored in a designated memory area of the memory chip, wherein the first data includes at least one of a portion of an access instruction and memory organization information, and wherein the access instruction is dependent on the type of memory chip. The method further comprises accessing the memory chip using the access instruction, the access instruction having been determined on the basis of the read first data.

Embodiments of the invention also- provide another method for accessing a memory chip in a manner dependent on a type of the memory chip. The method comprises, during a first portion of a boot sequence of a system, reading, by a memory reading unit, first data from the memory chip using a first read instruction, wherein the first data is stored in a designated memory area of the memory chip, wherein the first data includes one of at least a portion of a memory-chip-type-specific access instruction and memory organization information needed for accessing another portion of the memory chip, and wherein during the first portion of the boot sequence the memory reading unit is incapable of accessing the other portion of the memory chip as the access instruction has not yet been determined. The method further comprises, during a second portion of a boot sequence of the system, accessing the memory chip using the access instruction, the access instruction having been determined on the basis of the read first data.

Another embodiment of the invention provides a memory chip, wherein an access method for the memory chip is dependent on a type of memory chip used. The memory chip comprises a designated memory area of the memory chip and first data, stored in the designated memory area, wherein the first data is accessible using a first read instruction and wherein the first data includes one of a portion of at least one access instruction and memory organization information. The at least one access instruction is dependent on the type of memory chip and the at least one access instruction is determined on the basis of the first data.

In yet another embodiment of the invention, a computer system configured to boot from a memory chip is provided. The system comprises a random access memory and a flash memory chip wherein an access method for the memory chip is dependent on a type of memory chip used, the memory chip having a designated memory area containing at least one read instruction for accessing a second area of the memory chip, the second area of the memory chip containing at least one boot instruction. The system further comprises a processor configured to perform the steps comprising inputting a first read instruction to the flash memory chip, the first read instruction chosen to access the designated memory area of the flash memory chip, receiving, from the flash memory chip, a signal indicative of a successful read, and responsive to the signal, reading the at least one read instruction for accessing the second area of the memory chip. The processor further performs the steps comprising inputting the at least one read instruction to the memory chip, reading, from the second area of the memory chip, the at least one boot instruction, storing the at least one boot instruction in the random access memory, and executing the at least one boot instruction stored in the random access memory.

Another embodiment of the invention provides a computer system configured to boot from a memory chip. The system comprises a random access memory and a plurality of flash memory chips each of a different type, and wherein a respective access instruction for each memory chip is dependent on the type of the memory chip, each memory chip comprising a designated memory area containing at least one of a portion of a memory-chip-type-specific access instruction and memory organization information, and wherein each designated memory area is read by a read instruction different from the access instruction. The system further comprises a processor configured to perform the steps comprising inputting the read instruction to each flash memory chip, the first read instruction selected from a plurality of read instructions, receiving, from each flash memory chip, a signal indicative of a successful read of the respective designated memory area, and responsive to the signal, retrieving the respective access instruction. The processor further performs the steps comprising inputting the respective access instructions to the respective memory chips, and reading information from an area of the respective memory chips different from the respective designated memory areas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows an example of the memory organization of a NAND flash memory chip based on the prior art;

FIG. 2 shows a simplified illustration of the addressing when reading data from a NAND flash memory according to one embodiment of the invention;

FIG. 3 shows an exemplary signal diagram for the reading of a NAND flash memory chip according to one embodiment of the invention;

FIG. 4 shows an illustration of the interaction of system components when a system is started according to one embodiment of the invention; and

FIG. 5 shows a flowchart for an algorithm for reading the access information item according to one embodiment of the invention.

### DETAILED DESCRIPTION OF THE PREFERRED EMBODIMENT

1. Overview

In the case of the access method for a memory chip, the access is dependent on what type of memory chip is used. In this case, the method supports various types of memory chip. The term memory chip is understood to mean a semiconductor memory within the context of the application. In accordance with the inventive method, first data are first read from the memory chip which contains a memory-chip-typical information item for the access to the memory chip. The access to the memory chip is performed using the memory-chip-typical information item contained in the first data.

The particular first data may also be read without precise knowledge of the type of memory used, whereas more or less arbitrary access to the memory chip, for example the reading of any data or the entire memory content when the system is started up, is generally not possible without precise knowledge of the access instructions. The reading of the first data may be simplified by virtue of the first data being stored in a memory area which is particularly suitable for this purpose and which can easily be accessed even without precise knowledge of the type of memory chip used. Once the first data is known to the system as a result of having been read in, this information item can be used to access the memory chip.

According to one embodiment, no additional hardware complexity is required, since the method operates on a software basis. In this case, the method takes up merely a small memory area on the memory chip which stores the first data. The method gives rise to no costs other for this.

According to another embodiment, future types of memory chips are supported. This can be attributed, in particular, to the fact that the information item which is required for access is already held on the memory chip. For future types of memory chip, the information item then only needs to be adapted on the respective memory chip, without needing to perform any explicit updating, for example using an updated boot ROM, in the remaining system. The respective memory chip therefore also more or less provides the update. In this context, the method may dispense with the use of a manufacturer number and a type number, and, in particular, function-compatible memory chip types with different numbers are thereby supported. According to another embodiment, the inventive method may be used for access when the appropriate information item is provided even on memory chips with a design which differs significantly from that of other memory chip types.

According to another embodiment of the invention, at least one access instruction which is used according to the memory chip access type is dependent on what type of memory chip is used. The memory-chip-typical information item contained in the first data may be used to derive at least one access instruction. The actual access to the memory chip is performed by inputting the at least one access instruction. This embodiment of the invention affords the advantage that the at least one access instruction can be derived flexibly for a multiplicity of memory chip types.

According to another embodiment, the memory access can be performed by just one access instruction or by a plurality of access instructions. The latter may be the case when a plurality of memory areas are accessed.

In another embodiment, the memory-chip-typical information item may specify at least one access instruction, or a portion of the at least one access instruction, directly.

In yet another embodiment of the invention, the memory access may include reading of second data from the memory chip, the reading of the second data being prompted using at least one read instruction for reading the second data. This read instruction may be communicated to the memory via the appropriate interface.

In another embodiment, a respective reading instruction is generally dependent on a type of NAND flash memory chip used. NAND flash memory chips currently have no fixed standard for the read instruction which all manufacturers follow. Furthermore, the different organization of NAND memories typically results in many variations in the syntax of respective read instructions. Particularly for NAND flash memory chips, the great demand for NAND chips means that more developments can be expected in future which will also affect the syntax of the read instruction.

In another embodiment, at least one read instruction comprises a command statement and an address statement. In many NAND flash memory chips, it is possible to read using the command statement “00h”, which is one byte long. As used herein, the suffix “h” denotes the hexadecimal numerical representation. More recent NAND flash memory chips with a page size of 2048 bytes may use a command statement having a length of 2 bytes instead, the first byte having the value “00h” and the second byte having the value “30h”. In this case, the syntax of the read instruction is such that the address statement may come between the two bytes of the command statement.

According to another embodiment of the invention, the reading of the second data is part of a procedure for booting a system comprising the NAND flash memory chip. When a system is booted, memory contents in the NAND flash memory chip are copied to a RAM (Random Access Memory) chip. This may be necessary, in particular, because random access at byte or word level may not be possible in the case of a NAND flash memory chip, in contrast to a RAM. In addition, the access times in a NAND flash memory chip may be significantly longer as compared with a RAM. When program instructions for operating the system are copied from the NAND flash memory chip to the RAM chip during the boot process, this information transfer may also be called code shadowing. Since a NAND flash memory chip typically does not support XIP (execute in place), that is to say execution of program instructions stored in the memory chip, it may be necessary to resort to “code shadowing” for program instructions. In this case, apart from program instructions, it may also be possible to transfer other data, for example data files. The transfer of information from the NAND flash memory chip to the RAM chip may then allow the program instructions which have been read from the NAND flash memory chip and written to the RAM chip to be executed by the system.

In another embodiment of the invention, the address statement in the read instruction for reading the first data is a sequence of zeros. In one embodiment, this sequence may be a byte sequence of between 3 and 5 bytes which each have the value zero. By using an address statement to address a memory area on the NAND flash memory chip which is separate from other memory areas, the first data can be read more easily than the second data without the system's knowing the type of NAND flash memory used. Providing a separate memory area addressed using a sequence containing a plurality of bytes with the value zero is compatible with current memories because current NAND memories typically contain a memory area which can be addressed using a sequence containing a plurality of bytes with the value; but the number of bytes typically varies in the various NAND flash memory types (currently between 3 and 5 bytes). As described in detail later, however, it is possible to clear up the lack of explicitness in the syntax which is associated with this variation in the number of bytes.

According to an embodiment of the invention, the first data is stored in the first page of the NAND flash memory chip. The first page is typically denoted by the number 0 and is typically situated in block 0 of the NAND flash memory chip. This memory area may be addressed using a sequence of bytes with the value zero, as described above. Block 0 may differ from other blocks in current NAND flash memory types by virtue of the semiconductor fabricators' preventing storage errors for this block. Thus, according to one embodiment, this block cannot be an “invalid” or “bad” block. Accordingly, error detection or error correction may not be required in order to evaluate the first data. Error detection or error correction may be problematic because it is not possible to access the appropriate error indication information, also called EEC (Error Correction Code) information, without information about the size of the page. The reason for this is that the EEC information is located outside the normal memory area of a page, i.e. outside the area of a page which is determined by the page size. This memory area is referred to herein as an additional memory area. According to another embodiment, the first data may be stored in any page in block 0, without this necessarily being page 0. In this case too, it would be possible to ensure that the first data can be read and evaluated without error detection or error correction.

In another embodiment of the invention, the first data does not exceed a particular memory size. The first data may not exceed a particular size so that all or a large multiplicity of NAND flash memory types may be supported. Thus, the required memory size for the first data would not be greater than the smallest page size from the NAND flash memory types which are supported. For instance, if the memory size for the first data did not exceed the currently smallest page size of 256 bytes, the first data could generally be read from any type of NAND flash memory. Alternatively, if the memory size for the first data does not exceed the page size of 512 bytes, the first data can be read from any type of NAND flash memory with a page size of 512 bytes or more. This applies similarly for memory sizes for the first data with a maximum of 1024 bytes or 2048 bytes.

According to another embodiment of the invention, the first data comprises information relating to the memory organization of the NAND flash memory chip used. The information may relate in particular to the size of a page, to the number of pages per block or to the number of blocks in the NAND flash memory chip. In addition, information relating to the number of pages in the NAND flash memory chip may also be stored. Using these statements, it is possible to draw conclusions about the syntax of the read instruction. For example, NAND flash memory chips with a page size of 2048 bytes generally use 2 bytes for command statements. As used herein, the page size is understood to mean the normal memory area of a page without the additional memory area. The first data may also contain data regarding the page size which also takes into account the additional memory area.

In another embodiment, the first data comprise one or more parameter values for the at least one read instruction for reading the second data. A suitable parameter value is, in particular, the valid command statement for reading. For example, the command statement may comprise the byte “00h” or the bytes “00h” and “30h”. In this context, the second byte of the command statement may also represent a separate parameter value, separate from the parameter value of the first byte. In this case, this parameter value may be set to a fixed value if the respective memory chip does not require a second byte for the command statement. Alternatively, the first data may also comprise the byte length of the command statement. In addition, the parameter value provided may be the length of a column statement and/or the length of a row statement, for example, the respective number of bytes or bits. In this context, the column statement and the row statement may be part of the address statement. The column statement typically indicates from which byte of a page it is necessary to start the read process. The row statement typically determines from which page data needs to be read. Depending on the number of bytes per page or depending on the number of pages in the memory chip, the respective statement may be longer or shorter. For example, the column statement may have a length of 2 bytes and the row statement may have a length of 3 bytes. Using the parameter values, the reading unit may generate read instructions and may input them into the memory chip, allowing any page to be read.

In an alternative embodiment, the first data comprises a list of read instructions. Additionally, provision may also be made for the first data to contain a list of address statements from a plurality of read instructions. Providing such a list may be useful for the boot process. For example, using the first data, which already contains the necessary read instructions or address statements, the system may read content relating to the boot process from the memory chip and copy it to the system RAM store. In this context, control of the read process may be undertaken more or less by the NAND flash memory chip, since the reading unit merely inputs the instructions for reading the NAND flash memory chip into the latter. Provision may be made for the first data to be not yet completely compliant with the valid instruction syntax. For example, the command statement in the first data may not be repeated for every page, or it is also possible to dispense with this statement in the first data entirely.

Besides the information described above, the first data may also contain information which is not directly related to the access to the NAND flash memory chip, since these first data can be accessed easily. For example, information which allows individualized set-up of the system quickly during the boot process may be provided.

In another embodiment of the invention, the first data is read from the memory chip by a read instruction for reading the first data being read into the memory chip, said read instruction being selected from a plurality of possible read instructions. Each of read instruction may be valid for a different type of NAND flash memory chip. A plurality of possible read instructions may be tried out in succession by the reading unit for the purpose of reading the first data. For example, for reading page 0 in block 0 of a NAND flash memory, just four different type-specific options for the read instruction are currently known. To determine whether reading with a specific read instruction has been successful, an information item which is characteristic of a successful read may be read from the NAND flash memory chip. For example, the value of the Read/\overline{Busy} output of the NAND flash memory chip, which changes its value at least briefly prior to data output in the event of successful data output, may be used to indicate a successful read. In another embodiment, the explicit reading of the information item, for example the value of the Read/\overline{Busy} output, may not be necessary in order for the reading unit to recognize whether or not reading with the currently chosen read instruction is successful. For example, it may be possible to gauge the success of the access from the behavior of the data output of the NAND flash memory, that is to say of the I/O interface.

In yet another embodiment of the invention, provision may also be made for a read instruction for reading the first data to be read into the memory chip, wherein an end portion of the read instruction is not evaluated by the NAND flash memory chip. This may be the case where the read instruction is longer than the specified read instruction for the NAND flash memory chip used. According to one embodiment, the memory chip may ignore the instruction portion which goes beyond the specified read instruction and the memory chip may recognize the remaining portion as a valid read instruction. To this end, the read instruction chosen can be chosen such that it corresponds to the longest possible read instruction. To read page 0 in block 0, a read instruction of this type can comprise either the second byte of the command statement or the longest possible sequence of bytes with the value zero in relation to the address statement.

2. Detailed Description of the Drawings

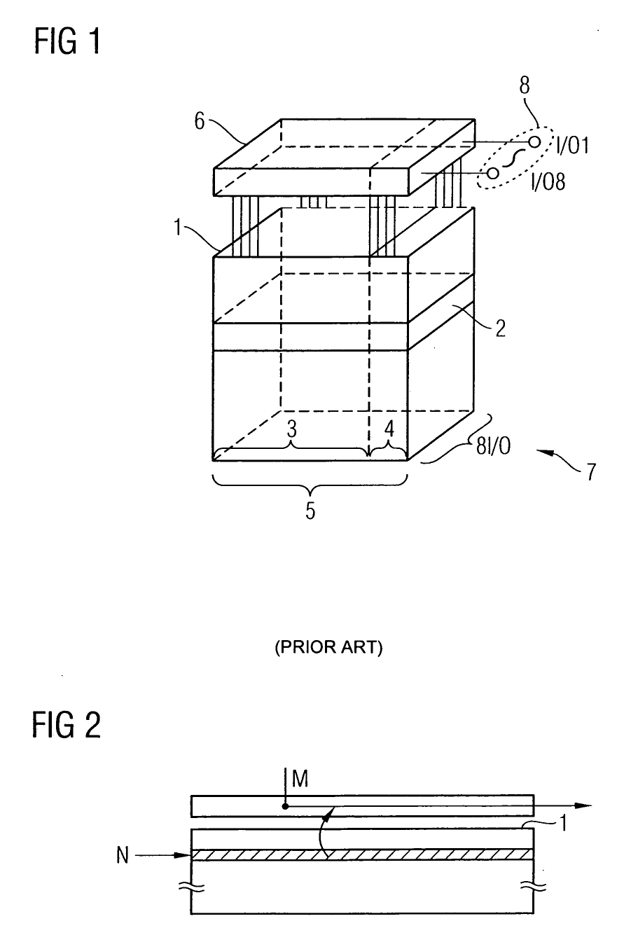

FIG. 1 shows an example of the memory organization of a NAND flash memory chip 7 based on the prior art. The memory chip 7 comprises a memory array 1 which is divided into a plurality of blocks 2, each block comprising a plurality of pages. In the present case, the memory array 1 is divided into 2048 blocks, with each block in turn comprising 64 pages, which means that the memory array 1 contains a total of 131072 pages. Each page comprises a plurality of bytes. The total number 5 of bytes in each page is divided into a normal memory area 3 and an additional memory area 4, the additional memory area being used for error correction. In the present case, the normal memory area 3 of a page comprises 2048 bytes, with the additional area 4 containing 64 bytes. In addition, the NAND flash memory chip 7 contains a data register 6 which has the size of a page. This is connected to the memory array 1. The read and write access operations in a NAND flash memory are carried out at page level, as already mentioned. Only the erase access operation is carried out at block level. In the case of a read access operation, the data which are to be read from a page are read from the memory array 1 into the data register 6 and can then be output via a parallel interface 8. The parallel interface 8 is a two-way interface and generally comprises eight I/O connections I/O1 to I/O8. In some NAND flash types, however, the parallel interface 8 has 16 parallel connections. In the case of a read access operation, this interface 8 is used both to read data and to transfer the read instruction to the memory chip. At present, a large number of different types of NAND flash memory chips are available on the market. These differ in terms of their memory organization in the size of a page (256, 512 or 2048 bytes), in the size of a block (8 KB, 16 KB or 128 KB) and in the total size of the memory (4 MB to 256 MB).

FIG. 2 shows a simplified illustration of the addressing when reading data from the memory array 1 according to one embodiment of the invention. The addressing is performed by stating the page N which is to be read and by stating the “column” M. In this case, the column statement M indicates which byte M of page N data from page N should be output via the interface 8.

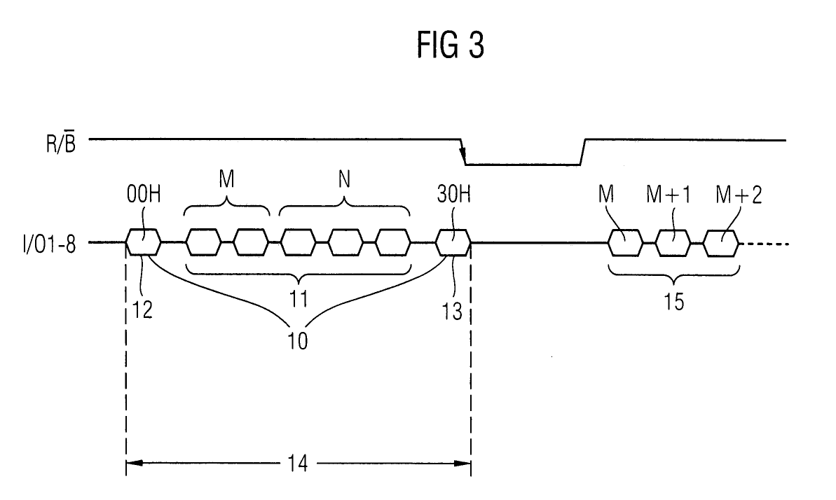

FIG. 3 shows an exemplary signal diagram for the reading of a NAND flash memory chip according to one embodiment of the invention. In this context, the bottom diagram shows the signal profile on the I/O interface 8 with the parallel bit lines I/O1 to I/O8. First, a read instruction 14 is read into the memory chip 7 via the parallel bit lines I/O1 to I/O8. A typical read instruction 14 contains a command statement 10 and an address statement 11. Depending on memory type, the command statement comprises one or two bytes. Memories with a page size of 2048 bytes and more generally use two bytes (e.g. 00h and 30h) as command statement, whereas memories with a small page size generally use one byte (e.g. 00h). In the present case, two bytes, namely byte 12 with the value 00h and byte 13 with the value 30h, are used for reading the data. The address statement 11 contains the statement M of the column byte (column statement) and the statement N of the page which is to be read (row statement). In the example shown in FIG. 3, the statement M and the statement N comprise 2 and 3 bytes, respectively, which means that a total of n=5 bytes are used for the address statement. In this case, not all bits of the bit lines I/O1 to I/O8 of a byte may be used for the column statement M or row statement M. If bits are not used, they may be set to the logic low level. Depending on memory organization, the length of the address statement may be between 3 and 5 bytes. In addition, some memory types also have, besides the simple read instruction described above, one or more extended read instructions which support an offset within the page during reading.

The address statement 11 and the command statement 12 may be read into the address register or command register inside the memory and may be processed further in said register, which means that the selected page may be copied to the data register 6. This process is indicated by the state change in the signal R/\overline{B} from the reading unit. The signal R/\overline{B} (Read/\overline{Busy}) indicates the status of the NAND flash memory chip. Typically, if this signal has the digital low value, this indicates that the memory array 1 is being accessed. When the signal returns to the digital high value, this means that the access to the memory array 1 has finished, i.e. that the data to be read are available in the data register 6 for output via the bit lines I/O1 to I/O8. The data to be read are then output as serial data bytes 15 via the bit lines I/O1 to I/O8. In some types of chip, output can take place at word level instead of at byte level.

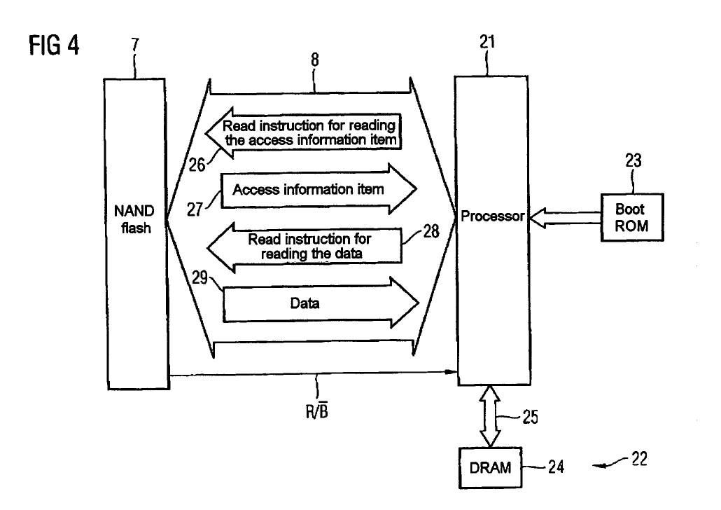

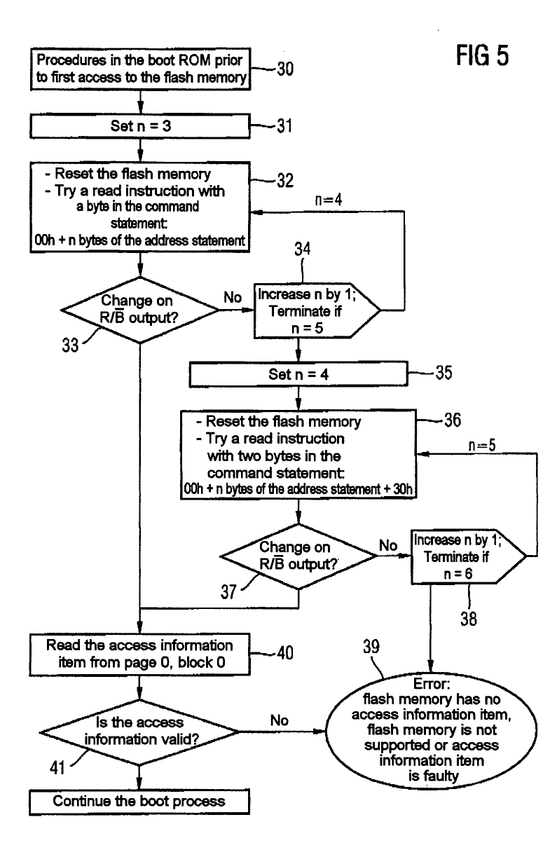

FIG. 4 shows the interaction of system components when a system 22 is started up, with the NAND flash memory chip 7 being accessed according to one embodiment of the invention. In one embodiment, the system 22 may be an “embedded system”, for example, which is an integral part of a larger technical system. Parts of the figures which have been provided with the same reference symbols in FIG. 1 and FIG. 4 correspond to one another. When the system 22 is started up, a processor 21 may read program instructions from a boot ROM 23. At a certain time during the boot process, program instructions and/or other data may be read from the NAND flash memory chip 7 via the I/O interface 8 by the processor 21 and may be transferred to a DRAM memory chip 24 via the interface 25. This read process is initiated by the program instructions in the boot ROM 23. In this case, the program instructions in the boot ROM 23 may support a large number of different NAND flash memory chip types. The transfer of the program instructions from the NAND flash memory chip 7 is may be necessary since—as already mentioned—the NAND flash memory chip 7 may not support the execution of program instructions stored in the memory chip, also referred to as XIP. There may even be provision during the boot process for the entire memory content of the NAND flash memory chip 7 to be transferred to the DRAM memory chip 24.

For the read access to the NAND flash memory chip 7, the processor 21 typically needs to know the valid memory-type-specific read instruction. According to one embodiment of the invention, the NAND flash memory chip 7 stores a memory-type-specific access information item in page 0 of block 0. To read the access information item, the valid read instruction 26 may be input into the NAND flash memory chip 7 via the interface 8. The access information item 27 may then be transferred to the processor 21 via the interface 8. The access information item 27 may comprise statements relating to the organization of the memory, for example the size of a page, the number of pages per block and/or the number of blocks in the NAND flash memory chip. In addition, the access information item may comprise one or more parameter values for the memory-chip-typical read instruction, for example the command statement for reading. Furthermore, it may also contain parameters for the address statement, e.g. the byte length of the column statement and/or the byte length of the row statement. Alternatively, the access information item may also contain a read instruction, a list of read instructions or fundamental portions of the read instruction or instructions directly. The access information item thus contains the necessary information for accessing other pages in the NAND flash memory 7.

In order to be able to access any pages in the NAND flash memory 7 during the boot process, the boot ROM typically needs to support error detection of incorrect blocks. If the boot ROM does not support error detection, then typically only other pages from the block 0 may be accessed during the boot process on the basis of the access information item. Using the access information item 27, it is possible to derive one or more read instructions 28 for reading one or more pages of the NAND flash memory 7, said read instructions being input into the NAND flash memory chip 7. On the basis of this, program instructions and/or other data 29 may be read from the NAND flash memory chip 7 and may then be forwarded to the processor 21 via the interface 8. These data 29 may then be written to the DRAM chip 24.

FIG. 5 shows a flowchart for an algorithm for reading the access information item 27 from page 0 of block 0 in the NAND flash memory 7 according to one embodiment of the invention. The algorithm may be based on read instructions being successively tried by the processor 21 from a plurality of possible read instructions in order to read the access information item 27. To read page 0 of block 0 in any NAND flash memory 7, at least four different read instructions are conceivable. First, when the system 22 is started up, a multiplicity of procedures 30 are performed which are independent of an access operation to the NAND flash memory chip 7. In step 31, the variable n is set to the value 3. In this case, the variable n indicates the number of bytes in the address statement of the assumed read instruction 26. In step 32, the NAND flash memory chip 7 is first reset using a reset operation. A read instruction of length 4 bytes in the form “00h 00h 00h 00h” is then read into the NAND flash memory chip 7 via the interface 8. In this context, the first byte relates to the command statement and the three subsequent bytes relate to the address statement. The test 33 checks whether the output R/\overline{B} executes a logic signal change. If this is not the case, the variable n is increased to 4 in step 34. Step 32 is then repeated, with the read instruction now having the form “00h 00h 00h 00h 00h”. The trial 33 then checks whether the output R/\overline{B} reacts to this read instruction. If not, the testing-out of read instructions with just one command byte in line with step 34 is not continued. In step 35, n is set to the value 4. In step 36, the NAND flash memory chip 7 is first reset using a reset operation. Next, a read instruction of length 6 bytes in the form “00h 00h 00h 00h 00h 30h ” is read into the NAND flash memory chip 7 via the interface 8. In this context, the first and last bytes relate to the command statement and the four remaining bytes relate to the address statement. The test 37 then checks whether the output R/\overline{B} reacts to this read instruction. If this is not the case, the variable n is set to the value 5 in step 38. In step 36, a read instruction of length 7 bytes in the form “00h 00h 00h 00h 00h 00h 30h” is then read into the NAND flash memory chip 7 via the interface 8. If the output R/\overline{B} does not react to this read instruction, then there must be an error 39. On the other hand, if a logic signal change is detected at the output R/\overline{B} during the algorithm, then the access information item can be read from page 0 of block 0 in step 40. In step 41, a check is performed to determine whether the access information item is valid. If this is not the case, then there must be an error 39, otherwise the boot process is continued. An error 39 is present whenever no access information item is stored on the NAND flash memory chip 7, the NAND flash memory chip 7 used is not supported by the method or the access information item has a data error.

According to another embodiment, page 0 may be read from block 0 by choosing the read instruction directly such that it comprises a byte sequence which is as long as possible. For a large number of memory chip types, the end portion of the read instruction is not evaluated if the valid length of the instruction is exceeded, which means that the remaining portion is recognized as a valid read instruction. If the read instruction is chosen to be “00h 00h 00h 00h 00h 00h 30h”, for example, then it can be interpreted as valid instruction sequence “00h 00h 00h 00h”, as valid instruction sequence “00h 00h 00h 00h00h” or as valid instruction sequence “00h 00h 00h 00h 00h 00h 30h”, depending on the memory type.

If, by contrast, the read instruction is chosen to be “00h 00h 00h 00h 00h 30h”, then it can be interpreted as valid instruction sequence “00h 00h 00h 00h”, as valid instruction sequence “00h 00h 00h 00h 00h” or as valid instruction sequence “00h 00h 00h 00h 00h 30h”, depending on the memory type. In both cases, three read instructions are therefore supported.

While the foregoing is directed to embodiments of the present invention, other and further embodiments of the invention may be devised without departing from the basic scope thereof, and the scope thereof is determined by the claims that follow.

1. A method for accessing a memory chip in a manner dependent on a type of the memory chip, the method comprising:
reading first data from the memory chip using a first read instruction, wherein the first data is stored in a designated memory area of the memory chip, and wherein the first data includes at least one of a portion of an access instruction and memory organization information, wherein the access instruction is dependent on the type of memory chip; and
accessing the memory chip using the access instruction, the access instruction having been determined on the basis of the read first data.

2. The method of claim 1, wherein the first data comprises the entire access instruction.

3. The method of claim 1, further comprising, after reading and prior to accessing, determining a remaining portion of the access instruction.

4. The method of claim 1, wherein the memory chip is a flash memory chip.

5. The method of claim 4, wherein the flash memory chip is a NAND flash memory chip.

6. The method of claim 1, wherein an address statement in the first read instruction for reading the first data is a sequence of bytes which each have the value zero.

7. The method of claim 1, wherein accessing the memory chip using the access instruction is part of a procedure for booting a system comprising the memory chip.

8. The method of claim 1, wherein the designated memory area of the memory chip is page 0 of block 0 of the memory chip.

9. The method of claim 1, wherein the designated memory area of the memory chip does not exceed a particular memory size, wherein the particular memory size is chosen such that the first data may be placed in a single page on a plurality of chips having a plurality of page sizes and having a plurality of chip types.

10. The method of claim 1, wherein the first data comprises information describing a memory organization of the memory chip including at least one of a size of a page on the memory chip, a number of pages per block on the memory chip, and a number of total blocks in the memory chip.

11. The method of claim 1, wherein the first data comprises one or more parameter values for at least one read instruction for reading second data, wherein the first data comprises at least a part of a command statement, a length of a column statement as part of an address statement, and a length of a row statement as part of the address statement.

12. The method of claim 1, wherein the first data comprises at least one read instruction for reading second data.

13. The method of claim 1, wherein reading first data from the memory chip comprises:
inputting the first read instruction for the first data, the first read instruction being selected from a plurality of read instructions, wherein each of the read instructions are valid for a different type of memory chip;
detecting a signal from the memory chip wherein the signal is characteristic of successful reading; and
reading the first data from the memory chip using the first read instruction.

14. The method of claim 1, wherein reading first data from the memory chip comprises:
inputting the first read instruction for the first data, wherein a first portion of the first read instruction is evaluated and a last portion of the first read instruction is disregarded, and
reading the first data from the memory chip using the first portion of the first read instruction.

15. A method for accessing a memory chip in a manner dependent on a type of the memory chip, the method comprising:
during a first portion of a boot sequence of a system, reading, by a memory reading unit, first data from the memory chip using a first read instruction, wherein the first data is stored in a designated memory area of the memory chip, and wherein the first data includes one of at least a portion of a memory-chip-type-specific access instruction and memory organization information needed for accessing another portion of the memory chip and wherein during the first portion of the boot sequence the memory reading unit is incapable of accessing the other portion of the memory chip as the access instruction has not yet been determined; and
during a second portion of a boot sequence of the system, accessing the memory chip using the access instruction, the access instruction having been determined on the basis of the read first data.

16. The method of claim 15, wherein the first data is exclusive of at least one of a manufacture code and a memory type code and wherein determining the access method on the basis of the read first data is independent of acquiring the manufacture code and the memory type code.

17. A memory chip, wherein an access method for the memory chip is dependent on a type of memory chip used, comprising:
a designated memory area of the memory chip; and
first data, stored in the designated memory area, wherein the first data is accessible using a first read instruction and wherein the first data includes one of a portion of at least one access instruction and memory organization information, wherein the at least one access instruction is dependent on the type of memory chip and wherein the at least one access instruction is determined on the basis of the first data.

18. The memory chip of claim 17, wherein the first data comprises the entire at least one access instruction.

19. The memory chip of claim 17, wherein a remaining portion of the at least one access instruction is determined on the basis of the first data.

20. The memory chip of claim 17, wherein the memory chip is a flash memory chip.

21. The memory chip of claim 20, wherein the flash memory chip is a NAND flash memory chip.

22. The memory chip of claim 17, wherein an address statement in the first read instruction for reading the first data is a sequence of bytes which each have the value zero.

23. The memory chip of claim 17, wherein the designated memory area of the memory chip is page 0 of block 0 of the memory chip.

24. The memory chip of claim 17, wherein the designated memory area of the memory chip does not exceed a particular memory size, wherein the particular memory size is chosen such that the first data may be placed in a single page on a plurality of chips having a plurality of page sizes and having a plurality of chip types.

25. The memory chip of claim 17, wherein the first data comprises information for memory organization of the memory chip including at least one of a size of a page on the memory chip, a number of pages per block on the memory chip, and a number of total blocks in the memory chip.

26. The memory chip of claim 17, wherein the first data comprises one or more parameter values for at least one read instruction for reading second data, wherein the first data comprises at least a part of a command statement, a length of a column statement as part of an address statement, and a length of a row statement as part of the address statement.

27. The memory chip of claim 17, wherein the first data comprises at least one read instruction for reading second data from a second area of the memory chip.

28. The memory chip of claim 17, wherein the memory chip is configured to perform the following steps:
receiving the first read instruction for the first data, wherein a first portion of the first read instruction is evaluated and a last portion of the first read instruction is disregarded, and
outputting the first data from the memory chip using the first portion of the first read instruction.

29. A computer system configured to boot from a memory chip, the system comprising:
a random access memory;
a flash memory chip wherein an access method for the memory chip is dependent on a type of memory chip used, the memory chip having a designated memory area containing at least one read instruction for accessing a second area of the memory chip, the second area of the memory chip containing at least one boot instruction;
a processor, the processor configured to perform the steps comprising:
inputting a first read instruction to the flash memory chip, the first read instruction chosen to access the designated memory area of the flash memory chip;
receiving, from the flash memory chip, a signal indicative of a successful read;
responsive to the signal, reading the at least one read instruction for accessing the second area of the memory chip;
inputting the at least one read instruction to the memory chip;
reading, from the second area of the memory chip, the at least one boot instruction;
storing the at least one boot instruction in the random access memory; and
executing the at least one boot instruction stored in the random access memory.

30. A computer system configured to boot from a memory chip, the system comprising:
a random access memory;
a plurality of flash memory chips each of a different type, and wherein a respective access instruction for each memory chip is dependent on the type of the memory chip; each memory chip comprising a designated memory area containing at least one of a portion of a memory-chip-type-specific access instruction and memory organization information, and wherein each designated memory area is read by a read instruction different from the access instruction;
a processor, the processor configured to perform the steps comprising:
inputting the read instruction to each flash memory chip, the first read instruction selected from a plurality of read instructions;
receiving, from each flash memory chip, a signal indicative of a successful read of the respective designated memory area;
responsive to the signal, retrieving the respective access instruction;
inputting the respective access instructions to the respective memory chips; and
reading information from an area of the respective memory chips different from the respective designated memory areas.

31. The computer system of claim 30, wherein the information contains at least one boot instruction.

32. The computer system of claim 30, further comprising,
storing the at least one boot instruction in a random access memory; and
executing the at least one boot instruction stored in the random access memory.
